(19) United States
(12) Patent Application Publication
(10) Pub. No.: US 2009/0002941 A1
(43) Pub. Date: Jan. 1, 2009

(54) AIR-PERMEABLE, HYDROPHOBIC MEMBRANE USED IN A COMPUTER DEVICE

(76) Inventors: Rajiv Mongia, Fremont, CA (US); Weibo Chen, Hanover, NH (US); Michael G. Izenson, Hanover, NH (US); James J. Barry, Hanover, NH (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/772,068

(22) Filed: Jun. 29, 2007

(51) Int. Cl. H05K 7/20; C08F 14/18; C08G 63/183

(52) U.S. Cl. 361/690; 526/255; 528/300

(57) ABSTRACT

A mechanism to reduce liquid intrusion into an internal volume of a computer device. In some embodiments of the invention, air-permeable, hydrophobic means reduces an intrusion of liquid into a computer device by way of an airflow system. In another embodiment, the air-permeable, hydrophobic means includes an air-permeable, hydrophobic membrane. Other embodiments are described and claimed.

### BACKGROUND OF THE INVENTION

1. Field of the Invention

The invention relates generally to gas cooling of a computer device. More particularly, some embodiments of the invention relate to air cooling of a computer device which includes a hydrophobic membrane to reduce liquid intrusion into an interior volume of the computer device.

2. Background Art

Personal computer technology faces a growing challenge to keep computer devices cool during their operation. In order to maintain competitiveness, computer manufacturers are moving toward sleeker designs, which result in computer devices having smaller dimensions. As the size of these computer devices decreases and their processing power increases, the design of effective gas cooling (such as airflow cooling) becomes more difficult. This is particularly true for manufacturers of portable personal computers (PCs) such as laptops or notebooks, who give the industrial design of devices a priority that poses significant cooling challenges. Often, this is because the maintaining of a sleek design restricts the inclusion of bottom vents, side vents, and/or front vents in a device, for example. As a result, it is very difficult to maintain airflow through this type of computer device, which has led to computer devices that run very warm to the touch. Any alternative in the locating of transfer means (such as a vent or other opening) on a computer device is further limited by the potential exposure of such vents to liquid intrusion in the course of use and/or misuse by an operator. An intrusion of liquid into a computer device by way of an opening can lead to sudden and severe damage to component circuitry and/or power supplies, for example.

### BRIEF DESCRIPTION OF THE DRAWINGS

The various embodiments of the present invention are illustrated by way of example, and not by way of limitation, in the figures of the accompanying drawings and in which:

FIG. 1 is a diagram illustrating a computer device configured to reduce liquid intrusion according to some embodiments of the invention.

FIG. 2 is a diagram illustrating a computer device configured to reduce liquid intrusion according to other embodiments of the invention.

### DETAILED DESCRIPTION

FIG. 3 illustrates a computer device 300 according to some embodiments of the invention. Computer device 300 represents any device having a computing capability, where the providing of the computing capability may require a cooling of one or more components 330 of computing device 300. In some embodiments of the invention, the computer device may be one of a desktop computer, a laptop computer, a personal-digital assistant, tablet PC, and any similar device. To cool the one or more components 330, computer device 300 may include a transfer means to allow a flow of a gas through the interior volume 390. Interior volume 390 may be some or all of a space internal to computing device 300. In FIG. 3, such a transfer means is represented by opening 310, which allows a flow of gas represented by an inlet flow of gas 350. Alternatively or in addition, transfer means may include opening 320, which allows an outlet flow of gas 360. In some embodiments, the transfer means may include at least one inlet opening and one outlet opening. Openings 310 and 320 are shown as being located in a surface 395 of computer device 300, although transfer means may be variously located on one or more surfaces of computer device 300.

For purposes of illustrating some embodiments of the invention, opening 310 is shown as an inlet for a flow of gas 350 flowing into interior volume 390, while opening 320 is shown as an outlet flow of gas 360 flowing out of interior volume 390. In some embodiments, a single transfer means may at one time be an outlet for a flow of gas flowing out of interior volume 390, and at another time be an inlet for a flow of gas flowing into interior volume 390. The gas in a flow of gas may be any gaseous mixture of an environment that the computer device 300 is likely to operate in. In some embodiments, the gas comprises air. References to “air” are used herein in describing some embodiments of the invention. One of ordinary skill in the relevant art would appreciate that reference to “air” in descriptions of some embodiments of the invention herein may be extended to include any of a variety of air-like gases. It should be noted however, that the air-permeability of an air-permeable, hydrophobic means is described herein with particular reference to air.

Flow of gas 350 may flow into the interior volume 390 from an exterior of the computer device 300 and/or from another interior volume of the computer device 300. Similarly, flow of gas 360 may flow from the interior volume 390 to an exterior of the computer device 300 and/or to another interior volume of the computer device 300. Computer device 300 may optionally include one or more additional openings 370, 380 to aid cooling of the one or more components 330 by various additional flows of gas.

To prevent an intrusion of a liquid into interior volume 390 through a given opening, a flow of gas which passes through the given transfer means is directed to flow through an air-permeable, hydrophobic means 340, as described herein. In one embodiment, directing a flow of gas through an air-permeable, hydrophobic means 340 comprises positioning the air-permeable, hydrophobic means 340 proximate to an opening through which the flow of gas passes. In various embodiments, air-permeable, hydrophobic means 340 may be located entirely internal to computer device 300, partially internal to computer device 300, or in an external surface of computer device 300, for example. For purposes of illustrating some embodiments of the invention, flow of gas 350 is shown as directed through air-permeable, hydrophobic means 340. Alternatively or in addition, flow of gas 360 and/or other flows of gas may be variously directed through one or more other air-permeable, hydrophobic means, for example.

In some embodiments of the invention, surface 395 may be a top surface of computer 300. As is described herein, the risk of intrusion by a liquid into an interior volume 390 of a computer device 300 is increased where the computer device 300 has one or more openings in a top surface. This increased risk of intrusion through a top surface may be offset by directing the flow of air passing through the top surface opening through an air-permeable, hydrophobic means. Described herein are various embodiments for variously directing one or more flows of gas through air-permeable, hydrophobic means to reduce an intrusion of liquid into an interior volume of a computing device.

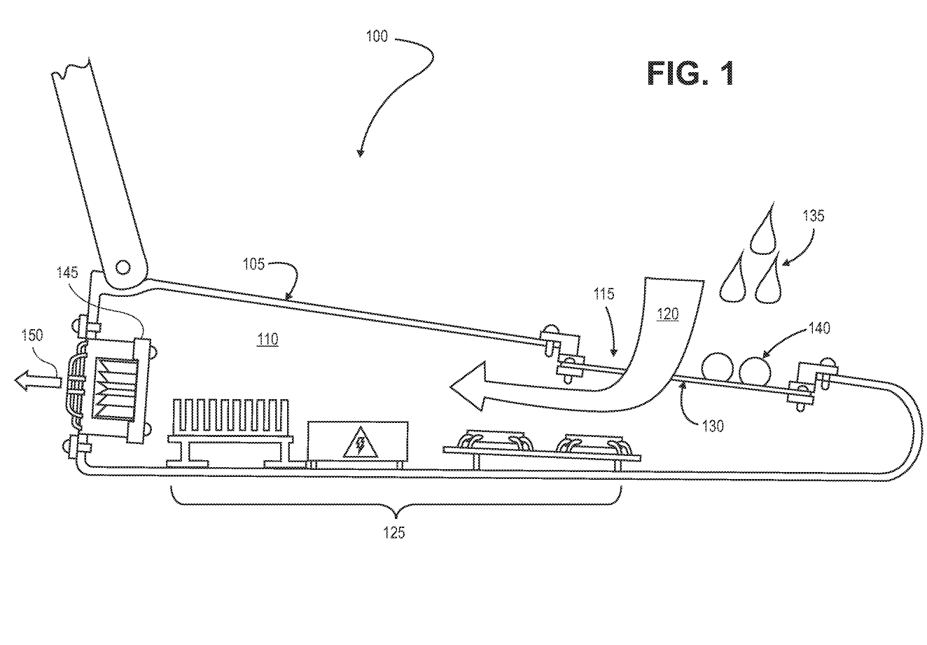

FIG. 1 is a diagram illustrating an example of a computer device 100 having a hydrophobic means for reducing liquid intrusion according to some embodiments of the invention. Computer device 100 represents any computing device which includes at least one transfer means for allowing a flow of air through an interior volume of the computer device 100. In various embodiments of the invention, computer device 100 may be any of a variety of portable computing devices. As used herein, portable computing device refers to any computing device which may operate while not being connected to a fixed (i.e. immovable) power supply. Examples of such portable computing devices include, but are not limited to, laptops, notebooks, desktop replacements, thin-and-lights, ultraportables, ultra-mobile personal computers (UMPCs), tablet PCs, personal-digital assistants (PDAs), and any other similar device which may include a transfer means for allowing a flow of air through the interior volume of the computer device. Alternatively, computer device 100 may be a non-portable device such as a desktop computer or a server, for example.

Computer device 100 has a surface 105 having at least one opening 115 for allowing a flow of air 120 through an interior volume 110 of computer device 100. Opening 115 may be any other transfer means for allowing a flow of gas, as discussed previously with reference to transfer means 310. The interior volume 110 represents at least part of any space which is internal to computer device 100. In one embodiment, interior volume 110 may represent a segregated compartment internal to computer device 110 having a dedicated air cooling system. The opening 115 represents any transfer means for allowing air to flow through interior volume 110. In one embodiment, the opening 115 may include an opening in a structure of computer device 100 which delimits at least part of interior volume 110. For example, opening 115 may be an inlet vent to allow a flow of air 120 between an inside of the interior volume 110 and an outside of the interior volume 110. Alternatively or in addition, such a transfer means may include, for example, any combination of outlet vents, flow passages or other means for allowing a flow of air through the interior volume 110. For brevity, discussion hereafter of embodiments of the invention will include references to a “vent” or “opening”. It is understood to one of ordinary skill in the art that descriptions of embodiments of the invention pertaining to a “vent” or “opening” may be extended to apply to any transfer means.

The flow of air 120 may be directed to cool one or more components 125 of computer device 100, as by convection, for example. In some embodiments, some or all of the one or more components 125 may be located in interior volume 110 through which the flow of air 120 is directed, as in the case of direct convection cooling. Cooling the one or more components is understood herein to mean reducing a temperature of at least one of the one or more components 125. The one or more components 125 represent any components of computer device 100 which may need to be cooled in aid of providing a computing capability of computer device 100. In one embodiment, the one or more components may include electrical components which are subject to heating during the operation of computer device 100. Examples of such components may include, but are not limited to, integrated circuits such as processors, computer memory, graphics hardware, power supplies, and heat dissipater devices.

In some embodiments of the invention the computer device 100 may further include a ventilation means for generating a flow of air 120. In various embodiments, this ventilation means may include, for example, a pressurized air supply and/or a vacuum mechanism. In FIG. 1, this ventilation means is represented by a fan 145 which draws outlet air 150 from interior volume 110 in aid of generating the flow of air 120. Additionally, other structures (not shown) may be incorporated into or configured with opening 115, interior volume 110 and/or a ventilation means such as fan 145 to efficiently direct air flow 120 for optimal cooling of one or more components 125. This may include, for example, a heat pipe and remote heat exchanger attached to the fan 145 for removing heat from a remotely located component. For brevity, discussion hereafter of embodiments of the invention will include references to “fan”. It is understood to one of ordinary skill in the art that descriptions of embodiments of the invention pertaining to a “fan” may be extended to apply to any ventilation means.

Depending on a user's regular use or misuse of computer device 100, and depending on the positioning of opening 115, interior volume 110 may be subject to intrusion by liquid 135. An intrusion of liquid 135 into interior volume 110 may be harmful to one or more components 125, and/or may be otherwise detrimental to the operation of computer device 100. In order to reduce any intrusion of liquid 135 into interior volume 110, some embodiments of the invention adds to computer device 100 an air-permeable, hydrophobic means for reducing an intrusion of any liquid into the interior volume of the computer device. In one embodiment, the flow of air 120 is to be directed through the air-permeable, hydrophobic means.

An air-permeable, hydrophobic means may include, but is not limited to, any combination of structures, materials, fabrics, coatings, and/or chemicals which provide both air-permeability and hydrophobicity. The air-permeable, hydrophobic means may provide its air-permeability by virtue of one or more characteristics including but not limited to its chemistry, porosity, structure, weave, thread count, coating, and configuration within computer device 100.

As used herein, the air-permeable, hydrophobic means are understood to be sufficiently “air-permeable” where the spatial velocity of an air flow through the air-permeable, hydrophobic means is equal to or greater than a minimum spatial velocity for a given pressure differential to which the air-permeable, hydrophobic means is exposed. The method for measuring the air-permeability of the air-permeable, hydrophobic means includes providing a reference pressure differential across the air-permeable, hydrophobic means and measuring to detect whether air flows through the air-permeable, hydrophobic means at a spatial velocity which is equal to or greater than the minimum spatial velocity required for the reference pressure differential provided. It should be noted that an adequate flow air for the computer device may also flow at pressure differentials lower than this provided pressure differential, as in cases where the air-permeable, hydrophobic means are more than sufficiently “air-permeable”. A measure of this air permeability can be represented by the “flow parameter,” which is the ratio of flow through an area of the air-permeable, hydrophobic means (e.g. measured in [mm³/(sec·mm²)], or (mm/sec)) divided by the pressure differential (e.g. measured in Pascals (Pa)) required for the flow. A membrane with a higher flow parameter will have higher air permeability. In some embodiments of the invention, the air-permeable, hydrophobic means is considered to be air-permeable where it has a flow parameter of at least 3.0 mm/(Pa·sec). This first level of air permeability is shown, at least, to support the air flow requirements of most personal computer devices having a transfer means for allowing a flow of air through an interior volume of the personal computer device. In other embodiments of the invention, the air-permeable, hydrophobic means is considered to be air-permeable where it has a flow parameter of at least 13.0 mm/(Pa·sec). This second level of air permeability is shown, at least, to support the air flow requirements of most portable computer devices having a transfer means for allowing a flow of air through an interior volume of the portable computer device.

Similarly, the air-permeable, hydrophobic means may provide its hydrophobicity by virtue of one or more characteristics including but not limited to its chemistry, porosity, structure, weave, thread count, coating, and configuration within computer device 100. Although hydrophobic means may repel any of a number of liquids according to various embodiments of the invention, hydrophobicity itself is defined herein with reference to the propensity to repel water.

The hydrophobicity of an air-permeable, hydrophobic means can be quantified by the minimum amount of water pressure required at an inlet of the air-permeable, hydrophobic means for water to leak through to an outlet of the air-permeable, hydrophobic means. The pressure at which drops of water first appear at an outlet of the air-permeable, hydrophobic means is taken as the water entry pressure of the air-permeable, hydrophobic means. It should be noted that water may also be prevented from intruding at pressures greater than this reference minimum pressure, as in cases where the air-permeable, hydrophobic means are more than sufficiently “hydrophobic”. Water entry pressure may be measured in pounds per square inch (psi), for example.

In some embodiments of the invention, the air-permeable, hydrophobic means is considered to be hydrophobic where it has a water entry pressure at least as high as 0.02 psi. This first level of hydrophobicity is shown to effectively eliminate any intrusion of water which is presented to the air-permeable, hydrophobic means in the form of incidental exposure such as rain, spray, mist, etc. In other embodiments of the invention, the air-permeable, hydrophobic means is considered to be hydrophobic where it has a water entry pressure at least as high as 0.1 psi. This second level of hydrophobicity is shown to effectively eliminate any intrusion of an amount of water which is presented to the air-permeable, hydrophobic means in greater amounts—e,g. by pouring, spilling, etc.—and allowed to pool thereon according to its own surface tension.

The air-permeable, hydrophobic means may include a single material and/or structure formed so as to be both air-permeable and hydrophobic, for example. The air-permeable, hydrophobic means may alternatively or additionally include plural, separate component means which are positioned in series with respect to a flow of air 120. The air-permeable, hydrophobic means may alternatively or additionally include plural, layered component means which are positioned adjacent to one another. The air-permeable, hydrophobic means may alternatively or additionally include plural, laminate component means which are chemically and/or mechanically held together. The air-permeable, hydrophobic means may alternatively or additionally include one or more of a mesh, a woven fibrous material, a non-woven fibrous material and a porous non-fibrous material.

In the exemplary embodiment of FIG. 1, membrane 130 represents the air-permeable, hydrophobic means. For brevity, discussion hereafter of embodiments of the invention will include references to “air-permeable, hydrophobic membrane,” or simply “membrane”. It is understood to one of ordinary skill in the art that descriptions of embodiments of the invention referencing an “air-permeable, hydrophobic membrane” (or simply a “membrane”) may be extended to apply to any air-permeable, hydrophobic means.

In various embodiments of the invention, membrane 130 may be made of any of a variety of hydrophobic materials. The variety of hydrophobic materials may include, but are not limited to, various types of hydrophobic polymers and copolymers. These polymers and copolymers include hydrophobic fluoropolymers such as polyvinylfluoride, fluorinated ethylene/propylene (FEP), tetrafluoroethylene/perfluoroalkyl perfluorovinylether copolymer (PFA), polytetrafluoroethylene (PTFE), polyethylene terephthalate (PET) etc. Some commercial products which comprise PTFE and/or PET and which are effective in implementing various embodiments of the invention include, but are not limited to, Gore-Tex® and Teflon®. The variety of hydrophobic materials also includes siloxanes and polymerized siloxanes (polysiloxanes) such as polydimethylsiloxane (PDMS) and silicone resins. Each of these materials may variously be used, for example, to form a hydrophobic structure of the membrane 130 and/or to form a hydrophobic coating on a structure of the membrane 130.

Referring again to FIG. 1, the membrane 130 may be positioned such that the flow of air 120 is directed through air-permeable, hydrophobic membrane 130. In this example, membrane 130 is positioned within interior volume 110, proximate to opening 115. As flow of air 120 is directed through air-permeable, hydrophobic membrane 130 any liquid 135 which may be directed toward opening 115 may collect as beads 140 on the air-permeable, hydrophobic membrane 130 without intruding into interior volume 110 of computer device 100.

The configuration of opening 115, membrane 130, and interior volume 110 with respect to each other may vary between different embodiments. In one embodiment, a membrane may be positioned on the outside of computer device 100, for example. Membrane 130 may thereby cover opening 115 from outside the computer device 100, being more readily available for cleaning and/or replacement by the user. Alternatively, or in addition, a membrane similar to membrane 130 may be positioned further inside interior volume 110 and away from opening 115. Alternatively, or in addition, at least part of an air-permeable, hydrophobic means may be positioned such that a flow of air is directed over, rather than through, the at least part of the air-permeable, hydrophobic means. In such an embodiment, air which is heated by components such as one or more components 125 may permeate up through an air-permeable, hydrophobic means to be vented away in the flow of air 120, while liquid in the flow of air 120 may be prevented from intruding down through the air-permeable, hydrophobic means toward the components. Membrane 130 may be held in place by use of adhesives for example. Alternatively or additionally, membrane 130 may be positioned, affixed and/or supported by any of a variety of mechanical and/or chemical means which are well know in the computer manufacturing arts. Accordingly, the various means of positioning, affixing and/or supporting membrane 130 are not discussed in any further detail herein, except as necessary to describe particular embodiments of the invention.

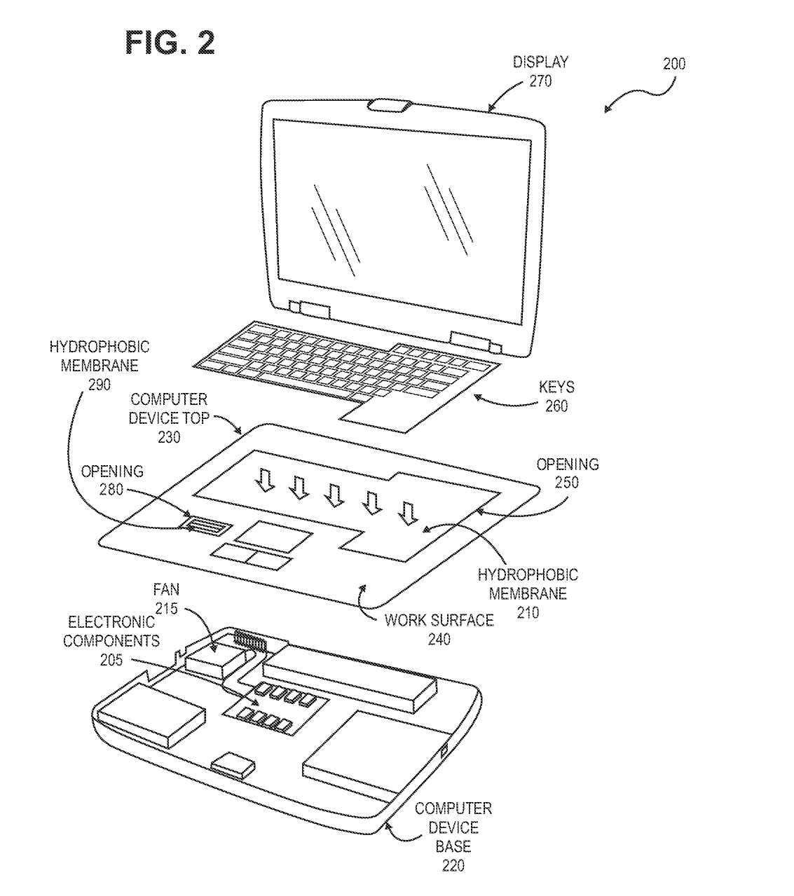

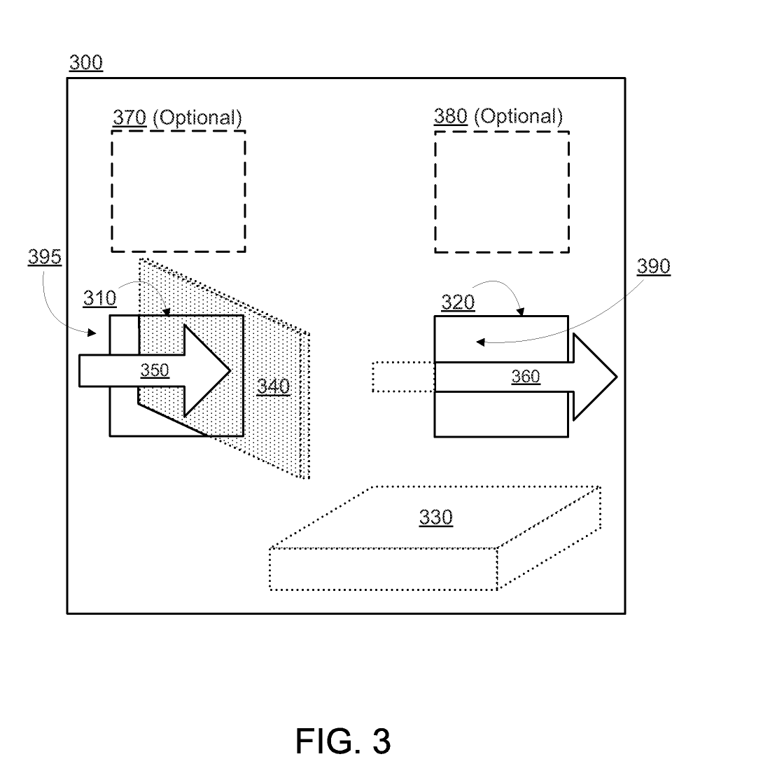

FIG. 2 includes a computer device 200 which is shown in an exploded view to illustrate some embodiments of the invention. Computer device 200 includes a computer device base 220 which is to be coupled to a computer device top 230 and keys 260 of a keyboard on a work surface 240 of computer device 200. When computer device base 220 is coupled to computer device top 230, at least one interior volume (not shown) is formed, in which components 205 are located. Components 205 represent an example of the one or more components discussed previously. A fan 215 may be included in computer device 200 to generate a flow of air to cool components 205.

Some embodiments of the invention may position an opening proximate to a “top” surface of computer device 200 while minimizing any liquid intrusion through the opening into an interior volume of computer device 200. As used herein, a top surface of a computer device is understood to refer to a surface of computer device 200 which, when computer device 200 is oriented according to any intended mode of operation, is facing substantially upward so as to be exposed to the possibility of liquid falling, spilling, pouring, etc. onto said surface. It is understood that computer device may have more than one top surface, insofar as one surface of computer device 200 may be considered a top surface with respect to one mode of operation of computer device 200, while a different surface of computer device 200 may be considered a top surface with respect to a different mode of operation of the computer device 200.

Alternatively or in addition, some embodiments of the invention may position an opening proximate to a “work” surface of computer device 200 while minimizing any liquid intrusion through the opening into an interior volume of computer device 200. In the exemplary case of computer device 200, opening 250 is in a top surface which is also a work surface 240. A work surface 240 is understood to be any surface which is designed to be exposed to various and frequent user contact in the course of normal operation of the computer device 200. An example of a work surface may be any surface having one or more user interface components such as a keyboard, touchpad, mousepad, buttons, etc. In one embodiment, an opening may be positioned proximate to where a user of computer device 200 would place their palms during use. When secured in position, keys 260 may be considered part of work surface 240. An opening such as opening 250 may be exposed to the possibility of liquid intrusion insofar as it is positioned with respect to a surface which is both a top surface and a work surface 240. However, a work surface of a computer device need not be top surface of the computer device, and vice versa. In one embodiment, the vent 250 may be placed proximate to the fan 215. This would minimize the size of the vent and membrane used, but still allow for appreciable flow.

An opening may be positioned proximate to a given surface by being an opening in the given surface, for example. Alternatively, an opening may be positioned proximate to a given surface by being an opening in a surface other than the given surface, where the opening nevertheless located near the given surface. In some embodiments of the invention, positioning an opening proximate to a given surface of computer device 200 includes positioning the opening in a surface underneath the given surface. In this embodiment, a flow of air is directed through the given surface in the course of flowing through the given opening.

By way of example, opening 280 may be positioned proximate to a top surface by being positioned in a surface on computer device top 230 which is a top surface. More particularly, the positioning of opening 280 in a top surface allows air to be directed through the top surface in the course of flowing through opening 280. Alternatively, opening 250 may be positioned with respect to a work surface 240 by being positioned under work surface 240. More particularly, opening 250 is positioned underneath keys 260, which are part of work surface 240, and air is directed through the surface including keys 260 (e.g. flowing between, around and/or under keys 260) in the course of flowing through opening 280.

Air flows through vents 250 and 280 are directed through hydrophobic membranes 210 and 290, respectively. Alternatively or in addition, an opening may be positioned with respect to a particular structure on work surface 240, wherein flow of air is directed around, through and/or under such a structure in the course of flowing through the opening. One example of such a structure is an ergonomic element such as a wrist rest (not shown).

The inclusion of membranes 210 and 290 in computer device 200 allows vents 250 and 280 to be positioned in work, top, or other surfaces of computer device 200 while liquid intrusion through those surfaces is reduced. This allows for greater variety in the positioning and/or sizing of vents for air cooling of computer device components. A relatively large opening 250 may be located beneath keys 260 of a keyboard on work surface 240. The size and air permeability of membrane 210 may result in significant airflows through one or more interior volumes of computer device 200. Meanwhile, the hydrophobicity of membranes 210, 290 may result in a reduction of liquid intrusion into one or more interior volumes of computer device 200.

Techniques for reducing an intrusion of liquid into a computer device are described herein. In the following description, numerous specific details are set forth. However, embodiments of the invention may be practiced without these specific details. In other instances, well-known structures and techniques have not been shown in detail in order not to obscure the understanding of this description.

What is claimed is:

1. A computer device comprising:
one or more components to be cooled by a flow of gas through an interior volume of the computer device;
an opening to allow the flow of gas through the interior volume; and
an air-permeable, hydrophobic membrane through which the flow of gas is to be directed.

2. The computer device of claim 1, wherein the air-permeable, hydrophobic membrane has a water entry pressure of at least 0.02 pounds per square inch (psi).

3. The computer device of claim 2, wherein the air-permeable, hydrophobic membrane has a water entry pressure of at least 0.1 psi.

4. The computer device of claim 1, wherein the flow of gas is to be directed through a top surface of the computer device.

5. The computer device of claim 4, wherein directing the flow of gas through a top surface on the computer device comprises locating the opening in the top surface of the computer device.

6. The computer device of claim 4, wherein the top surface of the computer device comprises one or more keys of a keyboard and wherein directing the flow of gas through the top surface of the computer device comprises locating the opening underneath the one or more keys of a keyboard.

7. The computer device of claim 4, wherein the top surface of the computer device comprises a wrist rest and wherein directing the flow of gas through the top surface of the computer device comprises locating the opening underneath the wrist rest on the top surface

8. The computer device of claim 1, wherein the air-permeable, hydrophobic membrane includes at least one material selected from a group consisting of polytetrafluoroethylene (PTFE) and polyethylene terephthalate (PET).

9. The computer device of claim 1, further comprising:
a fan to generate the flow of gas through the interior volume, where the opening is proximate to the fan.

10. A computer device comprising:
one or more components to be cooled by a flow of gas through an interior volume of the computer device;
a transfer means for allowing the flow of gas into the interior volume of the computer device;
an air-permeable, hydrophobic means through which the flow of gas is to be directed.

11. The computer device of claim 10, wherein the flow of gas is to be directed through a top surface on the computer device.

12. The computer device of claim 11, wherein the air-permeable, hydrophobic means is proximate to the transfer means.

13. The computer device of claim 11, wherein the top surface of the computer device comprises one or more keys of a keyboard and wherein directing the flow of gas through the top surface of the computer device comprises locating the opening underneath the one or more keys of a keyboard.

14. The computer device of claim 10, wherein the air-permeable, hydrophobic means has water entry pressure of at least 0.02 pounds per square inch (psi).

15. The computer device of claim 14, wherein the air-permeable, hydrophobic means has a water entry pressure of at least 0.1 psi.
